(19) United States
(12) Patent Application Publication
(10) Pub. No.: US 2009/0237878 A1
(43) Pub. Date: Sep. 24, 2009

(54) Electronic device structure

(75) Inventor: Cheng-Lung CHEN, Taipei County (TW)

Correspondence Address: RABIN & Berdo, PC, 1101 14TH STREET, NW, SUITE 500, WASHINGTON, DC, 20005, US

(73) Assignee: MICRO-STAR INT'L CO., LTD., Taipei (TW)

(21) Appl. No.: 12/149,649

(22) Filed: May 6, 2008

(30) Foreign Application Priority Data
Mar. 19, 2008 (TW) 097109719

(51) Int. Cl. H05K 7/00; G06F 1/16

(52) U.S. Cl. 361/679.55

(57) ABSTRACT

An electronic device structure includes a first member and a second member. The two members are pivotally connected to each other by one end in a rotatable way. A distance between one side of the first member adjacent to a pivot and the pivot is larger than a distance between a bottom surface of the second member and the pivot. When the first member rotates relative to the second member to an operation position, the side of the first member adjacent to the pivot has an outer edge leaning against a plane, such that the second member is placed on the plane with an inclined angle, and an airflow space is formed to assist thermal dissipation.

### CROSS-REFERENCE TO RELATED APPLICATIONS

This non-provisional application claims priority under 35 U.S.C. § 119(a) on Patent Application No(s). 097109719 filed in Taiwan, R.O.C. on Mar. 19, 2008, the entire contents of which are hereby incorporated by reference.

### BACKGROUND OF THE INVENTION

1. Field of Invention

The present invention relates to an electronic device structure, and more particularly to an electronic device structure placed on a plane with an inclined angle.

2. Related Art

Along with the rapid development of hi-tech industry including computer information and the expansion of the application range thereof, in order to satisfy requirements of the consumers on data processing speed, the operating speed of electronic components in a computer device must get higher, and further as the volume of the electronic component is getting smaller, the thermal generating intensity is increased accordingly. If the great amount of thermal energy cannot be dissipated in time, the electronic components may be damaged, and thus the stability and operation efficiency of the computer device may be affected.

Taking a notebook computer as an example, the notebook computer is usually placed on the desk for being operated, and thermal dissipation holes of the notebook computer are usually formed on the bottom surface. Thereby, the manufacturer may arrange a plurality of pads on the bottom of the notebook computer, so as to raise the notebook computer up a height. However, the current notebook computer has a rather high operation efficiency, and thus the thermal generated is increased a lot. Thereby, it is not enough to circulate the thermal dissipation airflow on the bottom of the notebook computer merely through the thermal dissipation effect of the spaces formed by the pads, such that the thermal in the device cannot be dissipated in a short time, and the thermal dissipation requirement of the current notebook computer having a high operation speed cannot be satisfied. Therefore, in order to achieve an ideal thermal dissipation effect, the notebook computer should be raised up a height to facilitate the airflow disturbance on the bottom of the notebook computer.

The conventional raise-up mechanism of a notebook computer is generally to mount a set of height adjustment mechanism on the notebook computer additionally. The common types are: disposing a protruding portion on a back panel of the notebook computer, so that when the back panel is turned on, the protruding portion rotates to the bottom of the notebook computer and leans against the desk to raise the notebook computer up a height; or disposing a support member and a set of adjustment device in the notebook computer, so as to make the notebook computer inclined forward and raised up a height through the engagement between the support member and the adjustment device; or disposing a stand respectively at two sides of the notebook computer, such that when the buckling mechanism for snapping the stands is released, the stands may pivotally rotate relative to the notebook computer, and each have one end leaning against the desk to raise up the notebook computer.

Although the above conventional art may raise the notebook computer up a height, so as to facilitate the thermal dissipation of the device and the manipulation of the user, the height adjustment mechanism and the notebook computer are two separate members and without direct interaction. When the user intends to raise up the notebook computer, the height adjustment mechanism must be adjusted additionally, so as to raise the notebook computer up to a height that the user gets used to, which is not convenient in use.

Moreover, the commonly known thermal dissipation method of a notebook computer is to add a thermal insulating board on the bottom of the notebook computer (disclosed in U.S. Pat. No. 7,161,799), and to dispose a plurality of risers on the thermal insulating board, such that a thermal dissipation gap is formed between the notebook computer and the thermal insulating board, so as to improve the thermal dissipation effect of the airflow disturbance. However, the thermal insulating board is an additional member to the notebook computer, and is inconvenient to take with the user who needs to carry the notebook computer out often.

In view of the above, the manufacturer has to add a height adjustment mechanism or thermal insulating board on a notebook computer. As the components of the height adjustment mechanism are complicated, it takes plenty of time in assembly, such that the manufacturing cost is increased, and the current requirement of a reduced cost in the manufacturing industry cannot be satisfied.

### SUMMARY OF THE INVENTION

Accordingly, the present invention is directed to an electronic device structure used for solving the problems in the conventional art that, as the height adjustment mechanism and the notebook computer have no direct interaction, the user must adjust the height adjustment mechanism additionally, or a thermal insulating board has to be further mounted on the bottom of the notebook computer, such that the operation process becomes complicated, the manufacturer needs to additionally fabricate and assemble the height adjustment mechanism, and the manufacturing cost is thus increased.

An electronic device structure of the present invention includes a first member and a second member. The first member and the second member are pivotally connected to each other by one end through at least one pivot, such that the first member and the second member rotate relative to each other to an operation position formed with an angle. A distance between an outer edge at one side of the first member adjacent to the pivot and an axle center of the pivot is larger than a distance between a bottom surface of the second member and the axle center of the pivot. When the first member and the second member are at the operation position, a distance is provided between the outer edge at one side of the first member adjacent to the pivot and the bottom surface of the second member, such that the second member is inclined with an angle, and, an airflow space is formed to assist thermal dissipation.

According to another embodiment of the present invention, an electronic device structure includes a first member and a second member. The first member and the second member are pivotally connected to each other by one end through at least one pivot, such that the first member and the second member rotate relative to each other to an operation position formed with an angle. At least one extending member is disposed at a position of the first member adjacent to the pivot, and a distance between an outer edge of the extending member to an axle center of the pivot is larger than a distance between the bottom surface of the second member and the axle center of the pivot. When the first member and the second member are at the operation position, a distance is provided between the outer edge of the extending member and the bottom surface of the second member, such that the second member is inclined with an angle, and an airflow space is formed to assist thermal dissipation.

The advantage of the present invention is that, as the first member rotates to the operation position, so as to support the second member directly, and the second member is placed with an inclined angle, and forms an airflow space with the plane for assisting thermal dissipation. It is unnecessary to add a height adjustment mechanism to the electronic device, so as to greatly simplify the height adjustment process, and thus reduce the manufacturing cost.

### BRIEF DESCRIPTION OF THE DRAWINGS

The present invention will become more fully understood from the detailed description given herein below for illustration only, and thus are not limitative of the present invention, and wherein:

FIG. 1A is an exploded view according to a first embodiment of the present invention;

FIG. 1B is a side view of the first embodiment of the present invention at an operation position;

FIG. 2A is an exploded view according to a second embodiment of the present invention;

FIG. 2B is a side view of the second embodiment of the present invention at a folding position;

FIG. 2C is a side view of the second embodiment of the present invention at an operation position;

FIG. 2D is a side view of the second embodiment of the present invention at the operation position;

FIG. 3A is a perspective view according to a third embodiment of the present invention;

FIG. 3B is a side view of the third embodiment of the present invention at an operation position;

FIG. 4 is a perspective view according to a fourth embodiment of the present invention;

FIG. 5 is a perspective view of the fourth embodiment of the present invention provided with a lifting hole; and

FIG. 6 is a perspective view of the fourth embodiment of the present invention provided with a lifting handle.

### DETAILED DESCRIPTION OF THE INVENTION

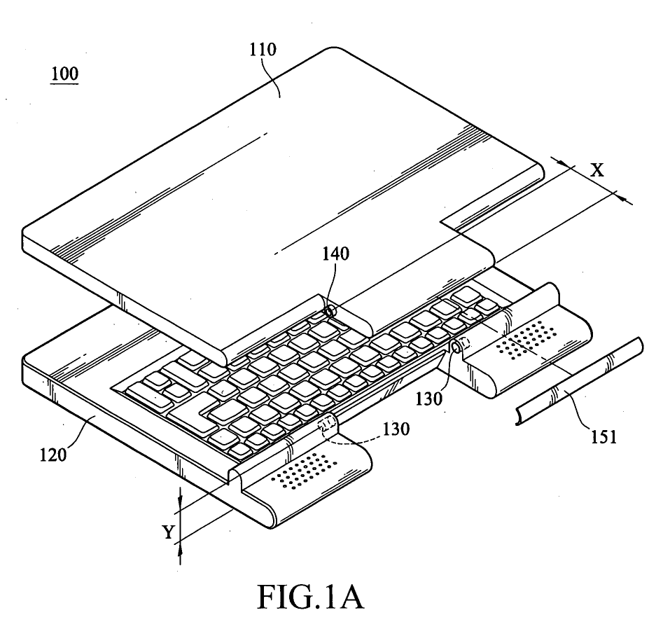

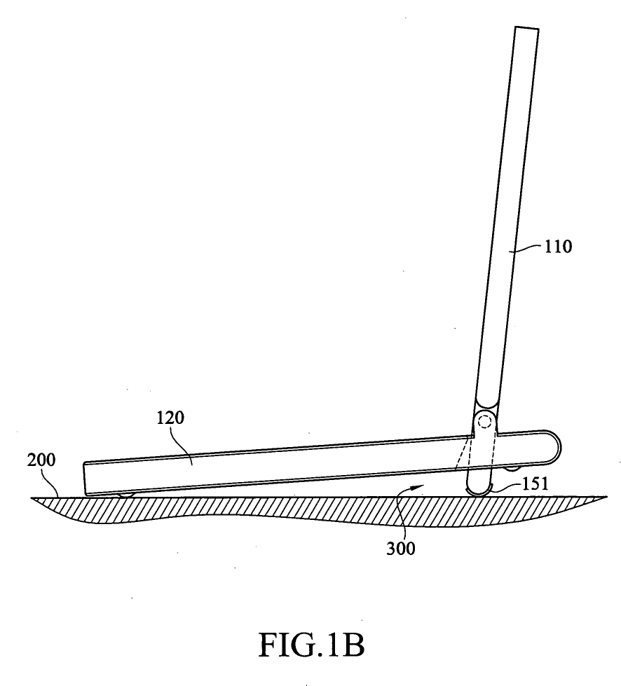

According to the electronic device structure of the present invention, the electronic device which likes a notebook computer, a flat panel computer, an ultra mobile personal computer (UMPC), and a personal digital assistant (PDA), but not limit to the above-mentioned flip-top electronic devices. In the detailed description of the present invention hereinafter, a notebook computer is taken as the most preferred embodiment of the present invention. However, the appended drawings are merely provided for reference and illustration, instead of limiting the present invention. Referring to FIGS. 1A and 1B, the electronic device 100 in a first embodiment of the present invention includes a first member 110 and a second member 120. The first member 110 is a display screen for displaying information related to the current operation. The second member 120 is a main body of the electronic device 100 for executing preset functions of the electronic device 100, but is not limited to this embodiment. The second member 120 is provided with two pivot holes 130 at one side, and the first member 110 has two pivots 140 corresponding to the pivot holes 130 and disposed protruding from one side. The pivots 140 are pivotally disposed in the pivot holes 130, such that the first member 110 rotates relative to the second member 120, so as to move to a folding position fitting the second member 120 and an operation position formed with an angle from the second member 120. A distance X between an outer edge at one side of the first member 110 adjacent to the pivot 140 and an axle center of the pivot 140 is larger than a distance Y between the bottom surface of the second member 120 and the axle center of the pivot hole 130. Please refer to FIGS. 1A and 1B, when the first member 110 rotates relative to the second member 120 to the operation position, the outer edge at one side of the first member 110 adjacent to the pivot 140 leans against a plane 200, such that the pivot end of the second member 120 is raised up a certain height, and the second member 120 is placed on the plane 200 with an inclined-angle. Thus, an airflow space 300 is formed between the second member 120 and the plane 200, so as to quickly dissipate the thermal generated by the electronic device 100. Moreover, an anti-slip pad 151 is further disposed at the outer edge of one side of the first member 110 adjacent to the pivot 140, for providing a frictional resistance to the first member 110, and thus the electronic device 100 is stably placed on the plane 200 without wobbling. It should be noted that, in the present invention, the outer edge at one side of the first member 110 adjacent to the pivot 140 is of a camber structure. When the relative angle formed between the first member 110 and the second member 120 is changed, the distance between the outer edge at one side of the first member 110 adjacent to the pivot 140 and the bottom surface of the second member 120 is changed accordingly. As such, when the operation angle of the first member 110 relative to the second member 120 is changed, the inclined angle of the second member 120 is also changed according to different positions of the outer edge at one side of the first member 110 adjacent to the pivot 140 leaning against the plane 200. Moreover, in accordance with the power generated when the electronic device 100 executes the preset functions, such as word processing or 3D graphics and image processing functions, the inclined angle of the second member 120 is adjusted corresponding to different leaning positions of the outer edge at one side of the first member 110, such that the airflow spaces 300 of different heights are formed between the second member 120 and the plane 200, so as to achieve the optimal thermal dissipation efficiency.

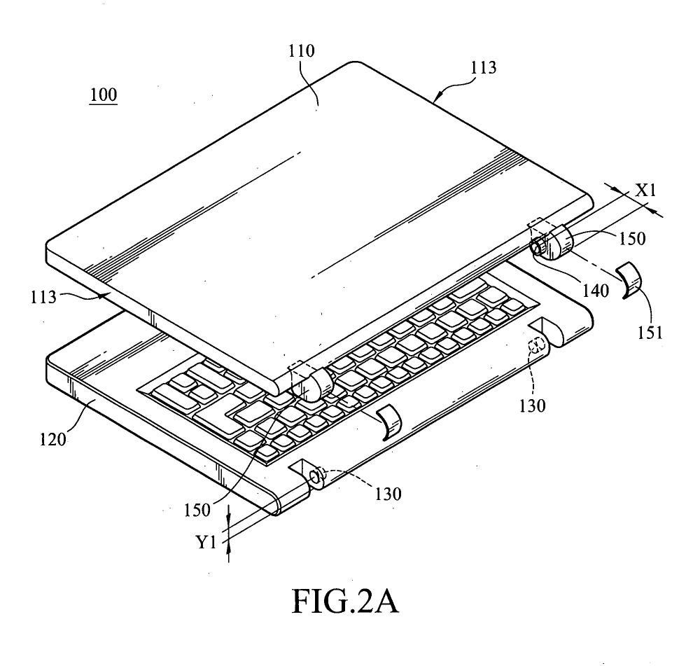

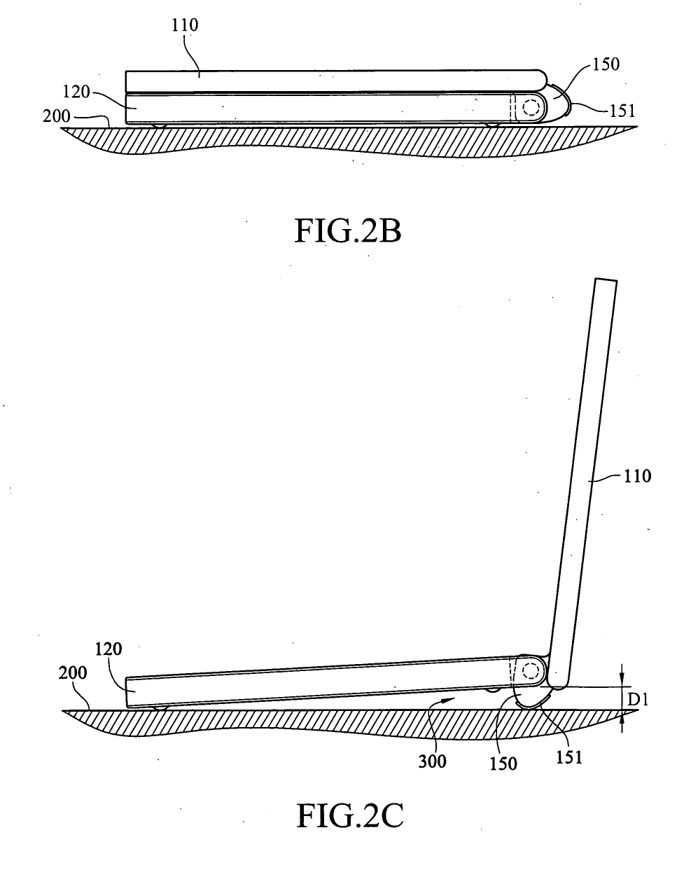

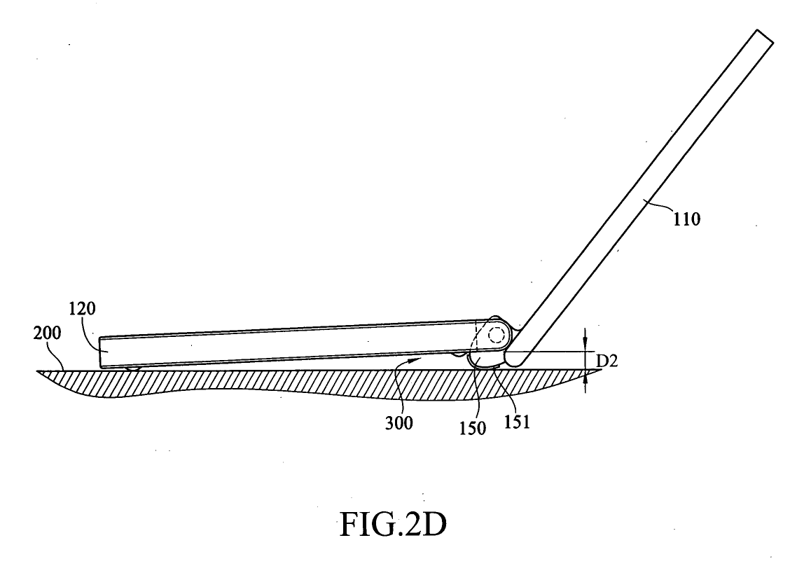

FIGS. 2A to 2C are schematic views according to a second embodiment of the present invention. The electronic device 100 in the second embodiment of the present invention includes a first member 110 and a second member 120. The second member 120 (i.e., the main body) is provided with two opposite pivot holes 130 at one side, and the first member 110 (i.e., the screen) has two pivots 140 corresponding to the pivot holes 130 and disposed protruding from one side. The pivots 140 are pivotally disposed in the pivot holes 130, such that the first member 110 rotates relative to the second member 120, so as to move to a folding position fitting the second member 120 and an operation position formed with an angle from the second member 120.

Referring to FIGS. 2A and 2C, two extending members 150 are formed on the outer edge at one side of the first member 110 adjacent to the pivots 140, and the pivot 140 is disposed protruding from one side of the extending member 150 respectively. A distance X1 between the outer edge of the extending member 150 and the axle center of the pivot 140 is larger than a distance Y1 between the bottom surface of the second member 120 and the axle center of the pivot 140. When the first member 110 rotates relative to the second member 120 to the operation position, the extending members 150 rotate accordingly, and the outer edge of the extending members 150 are a distance away from the bottom surface of the second member 120 and leans against a plane 200. Thereby, the pivot end of the second member 120 is raised up a certain height, such that the second member 120 is placed on the plane 200 with an inclined angle, and an airflow space 300 is formed between the second member 120 and the plane 200 to allow the airflow to pass through, so as to quickly dissipate the thermal generated by the electronic device 100. In addition, two anti-slip pads 151 are further disposed at the outer edge of the extending members 150 respectively, for providing a frictional resistance to the first member 110, and thus the electronic device 100 is stably placed on the plane 200 without wobbling.

As shown in FIGS. 2C and 2D, the outer edge at one side of the extending member 150 of the present invention is of a camber structure. When the relative angle formed between the first member 110 and the second member 120 is changed, the distance between the outer edge of the extending member 150 and the bottom surface of the second member 120 is changed accordingly. As such, when the operation angle of the first member 110 relative to the second member 120 is changed, the inclined angle of the second member 120 is also changed according to different positions of the outer edge of the extending member 150 leaning against the plane 200. Moreover, a large distance D1 between the second member 120 and the plane 200 as shown in FIG. 2C is changed into a small distance D2 between the second member 120 and the plane 200 as shown in FIG. 2D, in order to fit the power generated when the electronic device 100 executes the preset functions, such as word processing or 3D graphics and image processing functions. The inclined angle of the second member 120 is adjusted corresponding to different leaning positions of the extending member 150, such that the airflow spaces 300 of different heights are formed between the second member 120 and the plane 200, so as to achieve the optimal thermal dissipation efficiency.

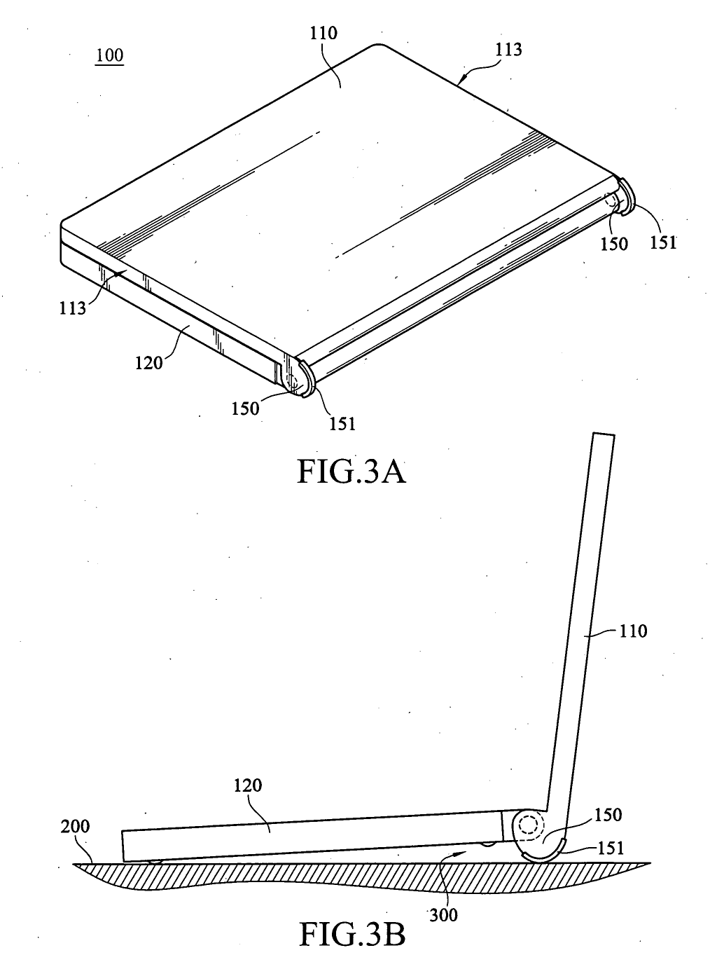

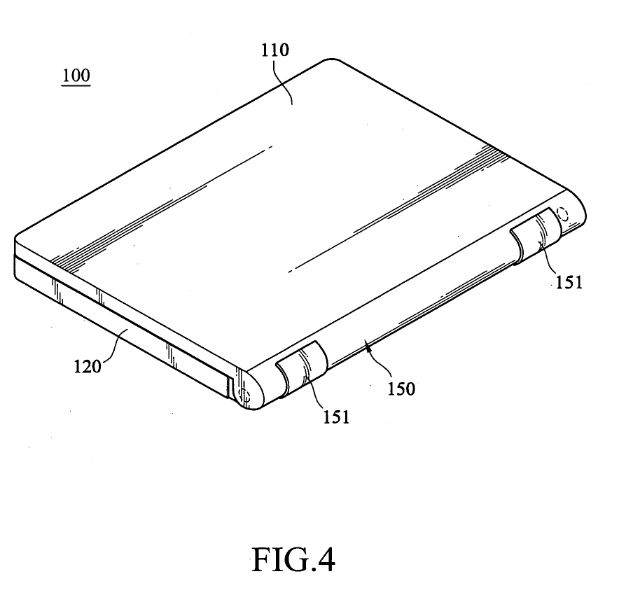

FIGS. 3A to 3C are schematic views according to a third embodiment of the present invention. The extending members 150 may also be respectively disposed on two opposite side edges 113 of the first member 110, and the distance between the outer edge of the extending member 150 and the axle center of the pivot 140 is larger than the distance between the bottom surface of the second member 120 and the axle center of the pivot 140. When the first member 110 rotates relative to the second member 120 to the operation position, the extending members 150 disposed on the first member 110 rotates accordingly. Moreover, the outer edge of the extending members 150 are a distance away from the bottom surface of the second member 120, and leans against the plane 200, such that the pivot end of the second member 120 is raised up a certain height, and the second member 120 is placed on the plane 200 with an inclined angle. Moreover, as shown in FIG. 4, in a fourth embodiment of the present invention, the two extending members 150 may be interconnected into an integrally formed extending member 150, so as to meet the requirement of the consumers on an overall attractive appearance of the electronic device 100.

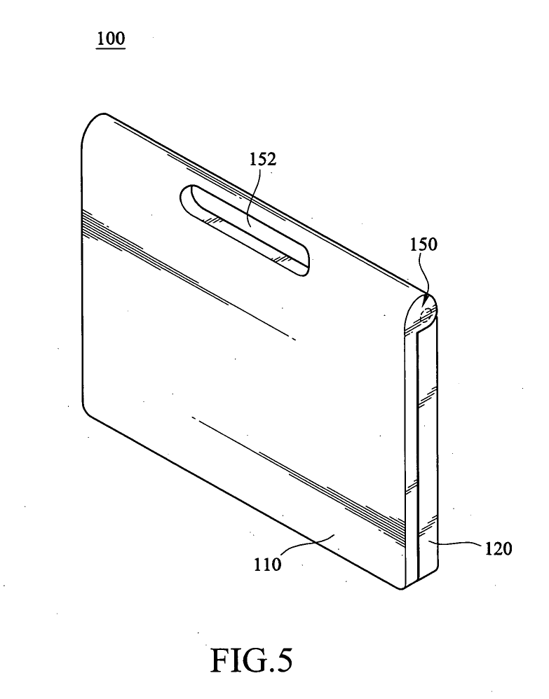

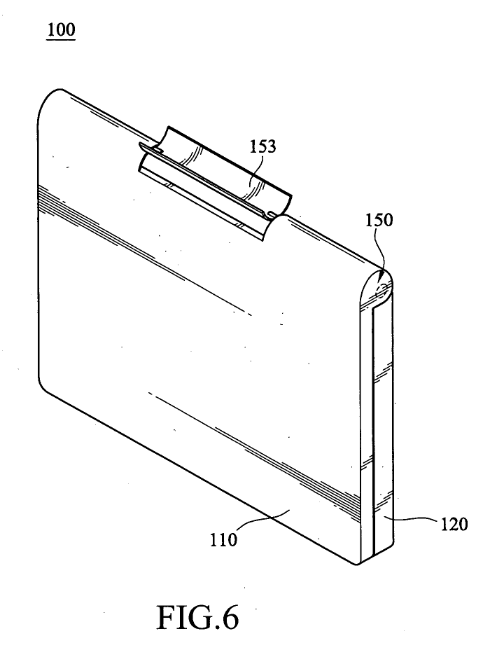

As shown in FIG. 5, in the fourth embodiment of the present invention, a lifting hole 152 is formed in the extending member 150 to facilitate the user to lift the electronic device 100 directly. As shown in FIG. 6, a lifting handle 153 is disposed in the extending member 150 of the fourth embodiment, and capable of rotating relative to the extending member 150, so as to facilitate the user to lift the electronic device 100, or rotate to a position fitting the extending member 150 to maintain an overall attractive appearance. In addition, the lifting handle 153 is formed through the engagement of the pivots and the pivot holes, such that the lifting handle 153 may rotate relative to the extending member 150.

In the electronic device structure disclosed in the present invention, when the first member (i.e., the screen) rotates to the operation position, i.e., when the extending member or one end of the first member leans against the plane, the second member (i.e., the main body) is raised up a height, such that the second member is placed on the plane with an inclined angle, and forms an airflow space with the plane to assist thermal dissipation, so as to effectively dissipate the thermal generated by the electronic device. In the absence of a height adjustment mechanism, the electronic device of the present invention may directly adjust the placing angle of the electronic device, so as to greatly reduce the time and process of height adjustment, and thus reduce the manufacturing cost.

What is claimed is:

1. An electronic device structure, comprising a first member and a second member, wherein the first member and the second member are pivotally connected to each other by one end through at least one pivot, such that the first member and the second member rotate relative to each other to an operation position formed with an angle; a distance between an outer edge at one side of the first member adjacent to the pivot and an axle center of the pivot is larger than a distance between a bottom surface of the second member and the axle center of the pivot; and when the first member and the second member are at the operation position, a distance is provided between the outer edge at one side of the first member adjacent to the pivot and the bottom surface of the second member.

2. The electronic device structure as claimed in claim 1, wherein the outer edge at one side of the first member adjacent to the pivot is of a camber structure, for changing the angle formed between the first member and the second member, and changing the distance between the outer edge at one side of the first member adjacent to the pivot and the bottom surface of the second member.

3. The electronic device structure as claimed in claim 1, wherein at least one the pivot is disposed on the side of the first member, the side of the second member has at least one pivot hole, and the pivot passes through the pivot hole.

4. The electronic device structure as claimed in claim 1, wherein the outer edge at one side of the first member adjacent to the pivot is further provided with an anti-slip pad.

5. The electronic device structure as claimed in claim 1, wherein at least one extending member is disposed at a position on the first member adjacent to the pivot, a distance between an outer edge of the extending member and the axle center of the pivot is larger than a distance between a bottom surface of the second member and the axle center of the pivot, and when the first member and second member are at the operation position, a distance is provided between the outer edge of the extending member and the bottom surface of the second member.

6. The electronic device structure as claimed in claim 5, wherein the outer edge of the extending member is of a camber structure, for changing the angle formed between the first member and the second member, and changing the distance between the outer edge of the extending member and the bottom surface of the second member.

7. The electronic device structure as claimed in claim 5, wherein at least one the pivot is disposed on the extending member, the side of the second member has at least one pivot hole, and the pivot passes through the pivot hole.

8. The electronic device structure as claimed in claim 5, wherein the first member has two side edges, and the two extending members are disposed on the two side edges respectively.

9. The electronic device structure as claimed in claim 5, wherein the outer edge of the extending member is further provided with an anti-slip pad.
